(19) United States
(12) Patent Application Publication
(10) Pub. No.: US 2011/0053314 A1
(43) Pub. Date: Mar. 3, 2011

(54) Method of Fabricating Top Gate Organic Semiconductor Transistors

(75) Inventors: Jeremy Henley Burroughes, Cambridgeshire (GB); Gregory Whiting, Mountain View, CA (US); Jonathan J. Halls, Cambridge (GB)

(73) Assignee: CAMBRIDGE DISPLAY TECHNOLOGY LIMITED, Cambridgeshire (GB)

(21) Appl. No.: 12/866,691

(22) PCT Filed: Feb. 6, 2009
(86) PCT No.: PCT/GB2009/000342

§ 371 Date: Nov. 9, 2010

(30) Foreign Application Priority Data
Feb. 6, 2008 (GB) 0802183.4

(51) Int. Cl. H01L 51/40

(52) U.S. Cl. 438/99; 257/E51.006

(57) ABSTRACT

The present invention provides a method of fabricating a top-gate organic semiconductor transistor comprising: providing a substrate; depositing a source and drain electrode over the substrate; depositing an organic semiconductor material in a channel between the source and drain electrode and over at least a portion of the source and drain electrodes; depositing a dielectric material over the organic semiconductor material; depositing a gate electrode over the dielectric material and organic semiconductor material in the channel; removing a portion of the dielectric material and organic semiconductor material, wherein the gate electrode acts as a mask to shield the underlying organic semiconductor material and dielectric material during the step of removing.

The present invention relates, in general, to a method of fabricating a top gate organic semiconductor field effect transistor. More particularly, the invention relates to the patterning of an organic semiconductor layer and dielectric layer forming part of the organic field effect transistor.

Transistors can be divided into two main types: bipolar junction transistors and field-effect transistors. Both types share a common structure comprising three electrodes with a semi-conductive material disposed there between in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semi-conductive material which conducts positive charge carriers (holes) or negative charge carriers (electrons) respectively. The semi-conductive material may be selected according to its ability to accept, conduct, and donate charge. The ability of the semi-conductive material to accept, conduct and donate holes or electrons can be enhanced by doping the material. The material used for the source and drain electrodes can also be selected according to its ability to accept and injecting holes or electrodes.

For example, a p-type transistor device can be formed by selecting a semi-conductive material which is efficient at accepting, conducting, and donating holes and selecting a material for the source and drain electrodes which is efficient at injecting and accepting holes from the semi-conductive material. Good energy-level matching of the Fermi-level in the electrodes with the HOMO level of the semi-conductive material can enhance hole injection and acceptance. In contrast, an n-type transistor device can be formed by selecting a semi-conductive material which is efficient at accepting, conducting, and donating electrons, and selecting a material for the source and drain electrodes which is efficient at injecting electrons into, and accepting electrons from, the semi-conductive material. Good energy-level matching of the Fermi-level in the electrodes with the LUMO level of the semi-conductive material can enhance electron injection and acceptance.

Transistors can be formed by depositing the components in thin films to form a thin film transistor (TFT). When an organic material is used as the semi-conductive material in such a device, it is known as an organic thin film transistor (OTFT).

Various arrangements for organic thin film transistors are known. One such device is an insulated gate field-effect transistor which comprises source and drain electrodes with a semi-conductive material disposed there between in a channel region, a gate electrode disposed adjacent the semi-conductive material and a layer of insulting material disposed between the gate electrode and the semi-conductive material in the channel region.

OTFTs may be manufactured by low cost, low temperature methods such as solution processing. Moreover, OTFTs are compatible with flexible plastic substrates, offering the prospect of large-scale manufacture of OTFTs on flexible substrates in a roll-to-roll process.

It is known to provide a gate electrode at the top of an organic thin film transistor to form a so-called top-gate organic thin film transistor. An example of a top-gate organic thin film transistor can be found in U.S. Pat. No. 6,734,505.

In such an architecture source and drain electrodes are deposited on a substrate and spaced apart to define a channel region there between. A layer of an organic semiconductor material is deposited in the channel region to connect the source and drain electrodes and may extend at least partially over the source and drain electrodes. An insulating layer of dielectric material is deposited over the organic semiconductor material and may also extend at least partially over the source and drain electrodes. A gate electrode is deposited over the insulating layer and located over the channel region.

The substrate may be rigid or flexible. Rigid substrates may be selected from glass or silicon and flexible substrates may comprise thin glass or plastics such as poly(ethylene terephthalate) (PET), poly(ethylene-naphthalate) PEN, polycarbonate and polyimide.

The organic semiconductive material may be made solution processable through the use of a suitable solvent. Exemplary solvents include mono- or poly-alkylbenzenes such as toluene and xylene; tetralin; and chloroform. Preferred solution deposition techniques include spin coating and ink jet printing. Other solution deposition techniques include dip-coating, roll printing and screen printing.

Preferred organic semiconductor materials include small molecules such as optionally substituted pentacene; optionally substituted polymers such as polyarylenes, in particular polyfluorenes and polythiophenes; and oligomers. Blends of materials, including blends of different material types (e.g. a polymer and small molecule blend) may be used.

For a p-channel OTFT, preferably the source and drain electrodes comprise a high work function material, preferably a metal, with a work function of greater than 3.5 eV, for example gold, platinum, palladium, molybdenum, tungsten, or chromium. More preferably, the metal has a work function in the range of from 4.5 to 5.5 eV. Other suitable compounds, alloys and oxides such as molybdenum trioxide and indium tin oxide may also be used. The source and drain electrodes may be deposited by thermal evaporation and patterned using standard photolithography and lift off techniques as are known in the art.

Alternatively, conductive polymers may be deposited as the source and drain electrodes. An example of such a conductive polymers is poly(ethylene dioxythiophene) (PEDOT) although other conductive polymers are known in the art. Such conductive polymers may be deposited from solution using, for example, spin coating or ink jet printing techniques and other solution deposition techniques discussed above.

For an n-channel OTFT, preferably the source and drain electrodes comprise a material, for example a metal having a work function of less than 3.5 eV such as calcium or barium or a thin layer of metal compound, in particular an oxide or fluoride of an alkali or alkali earth metal for example lithium fluoride, barium fluoride and barium oxide. Alternatively, conductive polymers may be deposited as the source and drain electrodes.

The length of the channel defined between the source and drain electrodes may be up to 500 microns, but preferably the length is less than 200 microns, more preferably less than 100 microns, most preferably less than 20 microns.

The gate electrode can be selected from a wide range of conducting materials for example a metal (e.g. gold) or metal compound (e.g. indium tin oxide). Alternatively, conductive polymers may be deposited as the gate electrode. Such conductive polymers may be deposited from solution using, for example, spin coating or ink jet printing techniques and other solution deposition techniques discussed above.

Thicknesses of the gate electrode, source and drain electrodes may be in the region of 5-200 nm, although typically 50 nm as measured by Atomic Force Microscopy (AFM), for example.

The insulating layer comprises a dielectric material selected from insulating materials having a high resistivity. The dielectric constant, k, of the dielectric is typically around 2-3 although materials with a high value of k are desirable because the capacitance that is achievable for an OTFT is directly proportional to k, and the drain current I_{D} is directly proportional to the capacitance. Thus, in order to achieve high drain currents with low operational voltages, OTFTs with thin dielectric layers in the channel region are preferred.

The dielectric material may be organic or inorganic. Preferred inorganic materials include Si0₂, SiNₓ and spin-on-glass (SOG). Preferred organic materials are generally polymers and include insulating polymers such as poly vinylalcohol (PVA), polyvinylpyrrolidine (PVP), acrylates such as polymethylmethacrylate (PMMA) and benzocyclobutanes (BCBs) available from Dow Corning. The insulating layer may be formed from a blend of materials or comprise a multi-layered structure.

The dielectric material may be deposited by thermal evaporation, vacuum processing or lamination techniques as are known in the art. Alternatively, the dielectric material may be deposited from solution using, for example, spin coating or ink jet printing techniques and other solution deposition techniques discussed above.

In a top-gate architecture, the dielectric material is deposited from solution onto the organic semiconductor and should not result in dissolution of the organic semiconductor. Techniques to avoid such dissolution include: use of orthogonal solvents that is use of a solvent for deposition of the uppermost layer that does not dissolve the underlying layer; and cross linking of the underlying layer.

The thickness of the insulating layer is preferably less than 2 micrometres, more preferably less than 500 nm.

Other layers may be included in the device architecture. For example, a self assembled monolayer (SAM) may be deposited on the gate, source or drain electrodes, substrate, insulating layer and organic semiconductor material to promote crystallity, reduce contact resistance, repair surface characteristics and promote adhesion where required. In particular, the dielectric surface in the channel region may be provided with a monolayer comprising a binding region and an organic region to improve device performance, e.g. by improving the organic semiconductor's morphology (in particular polymer alignment and crystallinity) and covering charge traps, in particular for a high k dielectric surface. Exemplary materials for such a monolayer include chloro- or alkoxy-silanes with long alkyl chains, e.g. octadecyltrichlorosilane. Similarly, the source and drain electrodes may be provided with a SAM to improve the contact between the organic semiconductor and the electrodes. For example, gold SD electrodes may be provided with a SAM comprising a thiol binding group and a group for improving the contact which may be a group having a high dipole moment; a dopant; or a conjugated moiety.

In order to fabricate an organic electronic circuit such as an active matrix display backplane it is necessary to pattern the core active components of an organic transistor such as the organic semiconductor and dielectric layers. Patterning allows each organic transistor to be isolated from each other and avoids the presence of a continuous organic semiconductor film which can introduce cross talk between organic transistors in the electronic circuit compromising circuit performance. Organic semiconductor and dielectric patterning is also required to open up vias to allow upper and lower metallisation layers to make contact.

One approach to patterning is to pattern the organic semiconductor layer or dielectric layers directly using targeted ink jet printing techniques. However targeting droplets of active material using a ink jet print head is challenging and due in part to differences of morphology between different ink formulations and process conditions, the performance of ink jet printed organic transistors is typically below that of corresponding organic transistors in which the layers have been coated by other techniques.

According to a first aspect of the present invention, there is provided a method of fabricating a top-gate organic semiconductor transistor comprising: providing a substrate; depositing a source and drain electrode over the substrate; depositing an organic semiconductor material in a channel between the source and drain electrode and over at least a portion of the source and drain electrodes; depositing a dielectric material over the organic semiconductor material; depositing a gate electrode over the dielectric material and organic semiconductor material in the channel; removing a portion of the dielectric material and organic semiconductor material wherein the gate electrode acts as a mask to shield the underlying organic semiconductor material and dielectric material during the step of removing.

The present invention therefore permits organic thin film transistor devices to be fabricated using coating techniques such as spin coating, dip-coating, roll printing, screen printing or ink jet flood printing. The top gate electrode acts as an etch stop mask allowing the organic semiconductor material and dielectric to be removed where it is not required. This removal reduces leakage, reduces cross-talk between components in a monolithic circuit and enables vias to be connected between upper and lower metallisation layers.

Preferably, the step of removing includes exposing the transistor to an etching process and therefore the gate electrode acts as an etch mask to protect the underlying organic semiconductor material and dielectric material from the etch.

A plasma etch is preferred, preferably comprising an O₂ or CF₄ plasma etch.

Advantageously, the dielectric and/or organic semiconductor material can be deposited using spin coating. Formulations for spin coating are known to provide lifetimes for materials in excess of formulations used for targeted ink jet printing techniques. Ink jet printing techniques can be employed however and advantageously different formulations and targeting placement techniques can be used since any excess dielectric or organic semiconductor material can is removed during the etch process. Accordingly, a preferred process for depositing the organic semiconductor material and dielectric is ink jet printing.

Preferably, the organic semiconductor material is a polymer. During the step of removing the substrate is preferably exposed and preferably a portion of the drain electrode is exposed.

The method also preferably includes depositing a conductive track over the exposed drain electrode and interconnecting the conductive track to an additional device. Optionally, the additional device is an organic light emitting diode or an additional transistor.

Embodiments of the invention will now be described, by way of example only, and with reference to the accompanying drawings of which:

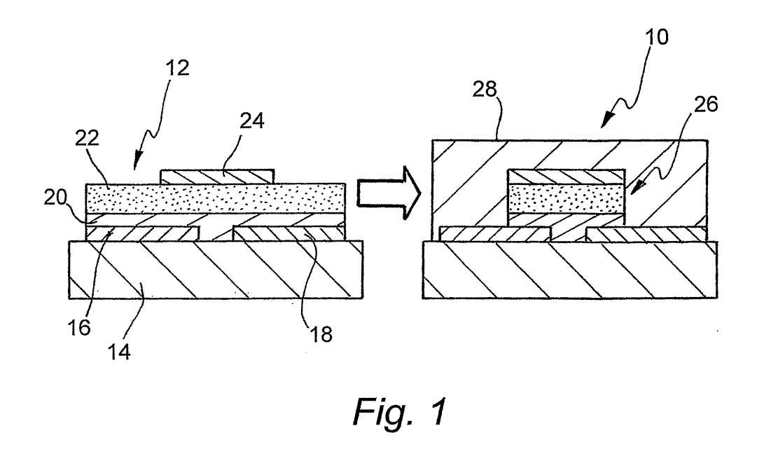

FIG. 1 is a schematic diagram of a fabricated top-gate organic semiconductor transistor according to a first embodiment of the present invention;

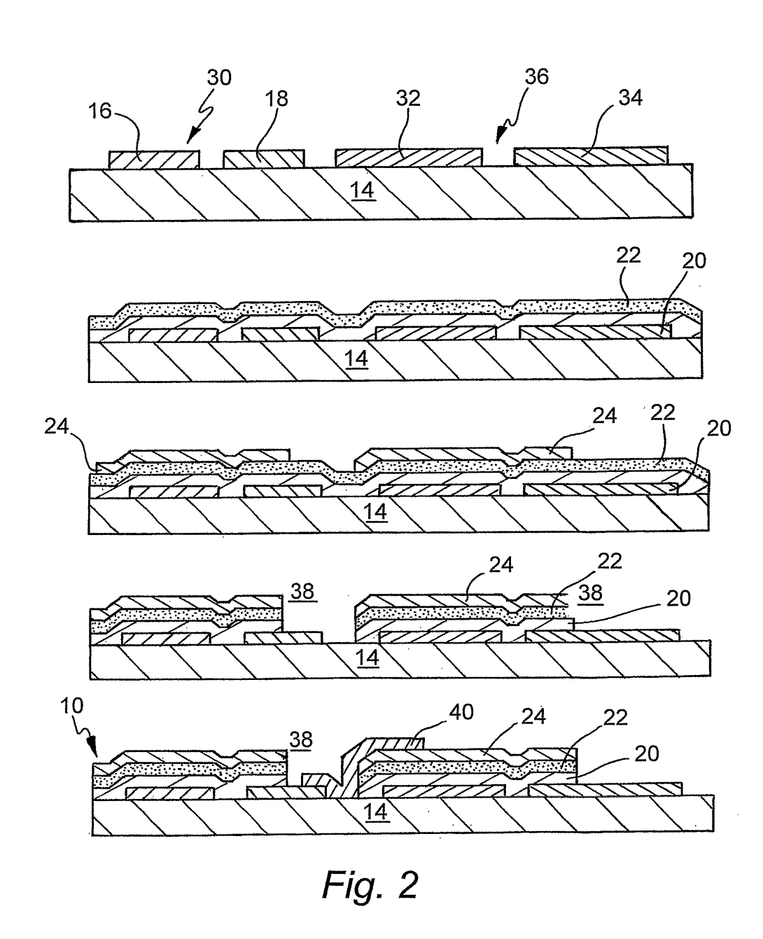

FIG. 2 is a schematic diagram of a method of forming interconnected devices according to a second embodiment of the present invention;

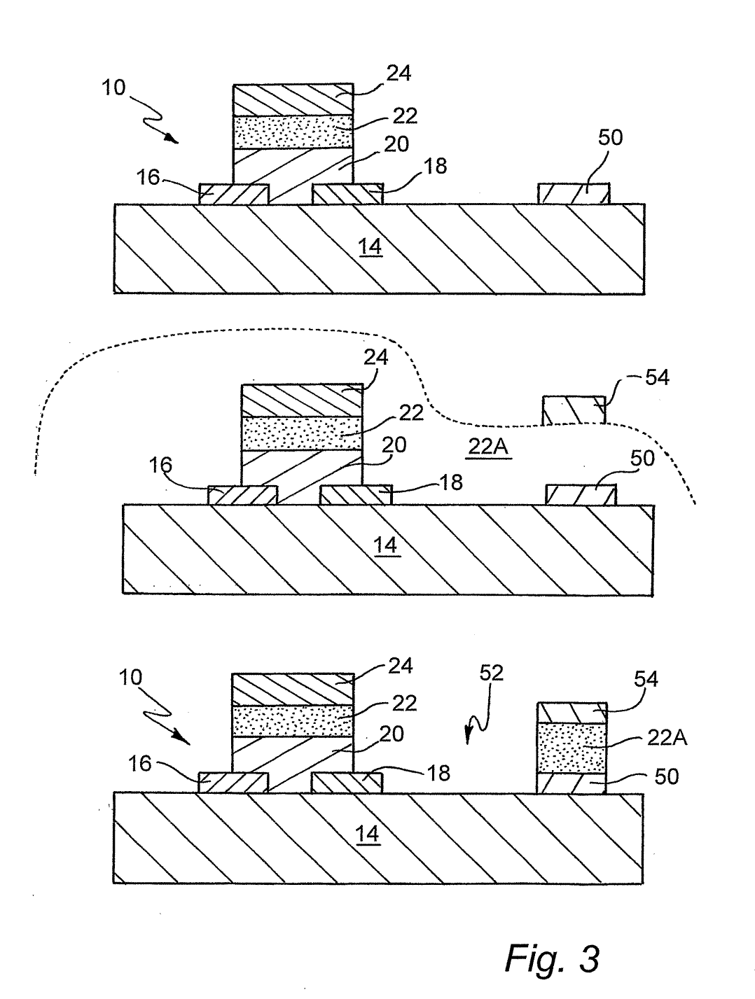

FIG. 3 is a schematic diagram of adjacent transistor and capacitor according to a third embodiment of the present invention;

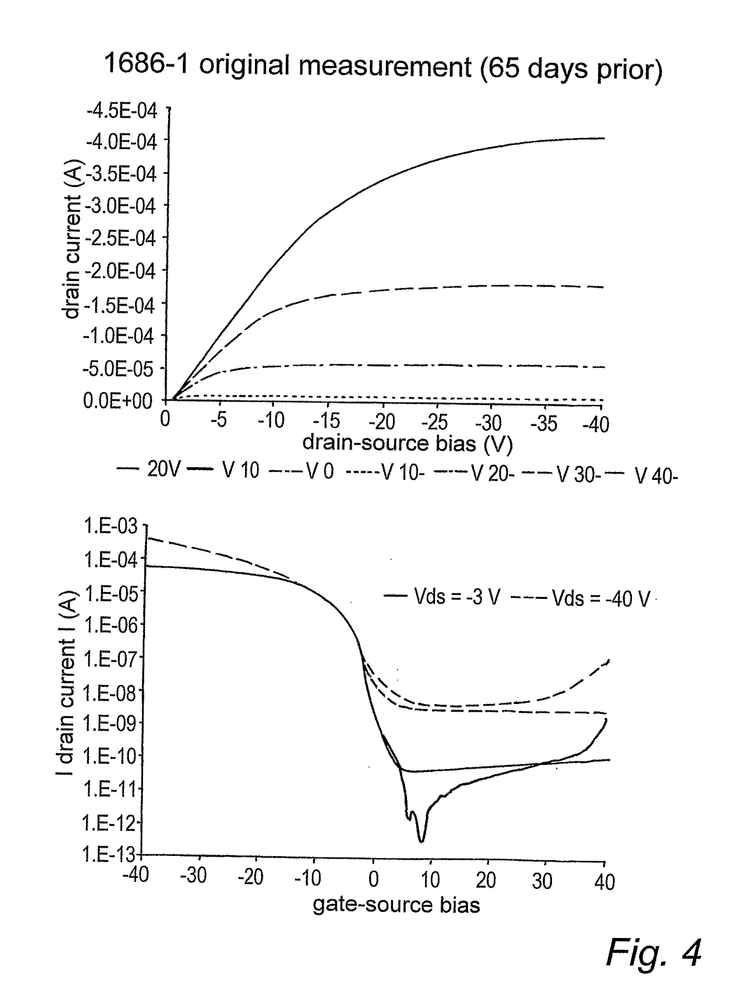

FIG. 4 is a graph of transistor properties prior to a plasma etch; and

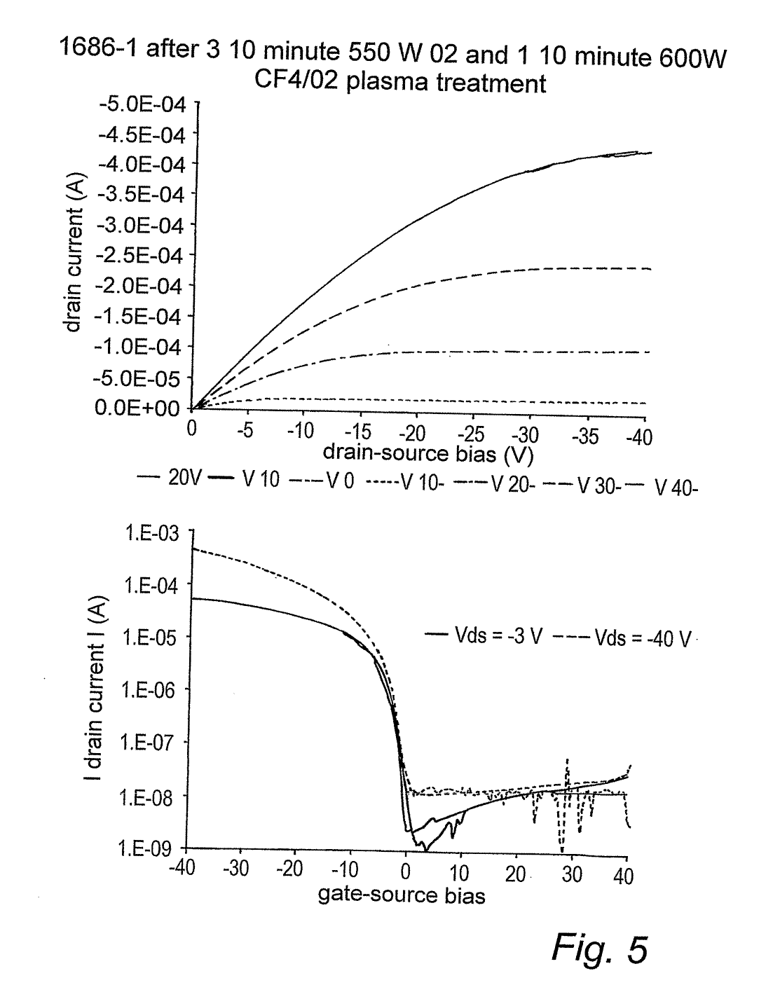

FIG. 5 is a graph of transistor properties after a plasma etch performed in accordance with the first embodiment of the present invention.

Throughout the following description like reference numerals shall be used to identify like parts.

Referring to FIG. 1, a schematic diagram of a top-gate organic semiconductor transistor 10 according to a first embodiment of the present invention is fabricated from a precursor top-gate organic transistor 12 comprising substrate 14, source and drain electrodes 16, 18, organic semiconductor material 20, dielectric 22, and gate electrode 24.

The precursor top-gate organic transistor 12 is exposed to an etching process until the exposed dielectric 22 and exposed organic semiconductor material 20 is removed. A portion of the dielectric 22 and organic semiconductor material 20 is not removed because the gate electrode 24 acts as a mask to the portion of the dielectric 22 and organic semiconductor material 20 which is directly beneath the gate electrode 24. Accordingly, a top-gate organic semiconductor transistor 10 is provided in which the stack 26 of active layers comprising organic semiconductor material 20 and dielectric 22 is isolated from neighbouring devices. Additionally, an encapsulation 28 can be fixed to the surface of the substrate 14 to encapsulate the stack 26 of active layers.

Referring to FIG. 2, one method of forming the top-gate organic semiconductor transistor 10 according to the first embodiment of the present invention of FIG. 1 is described in more detail with reference to a method of forming interconnected devices.

A substrate 14 is provided and metal contacts such as a source electrode 16 and drain electrode 18 of a switch transistor 30 are deposited and patterned upon the substrate 14 using either a vacuum deposition process through a shadow mask or by sputtering and subsequent photolithographic etching or lift-off. A suitable metal for both the source electrode 16 and drain electrode 18 is gold, Au. Further metal contacts are deposited and patterned upon the substrate 14 for neighbouring devices such as the source electrode 32 and drain electrode 34 of a neighbouring drive transistor 36.

An O₂ plasma etch is applied to clean the metal contacts and if required a self assembled monolayer or other surface treatment is applied to the metal contacts to promote crystallisation, reduce contact resistance, repair surface characteristics and promote adhesion where required.

Subsequently an organic semiconductor material 20 is coated over the entire area of the substrate 14. Suitable organic semiconductor materials 20 include polythiophene, amine-containing oligomers and polymers and solubilised polyacenes such as pentacene. Suitable coating techniques include blade coating, spin coating, spray coating and flood printing. A thermal treatment of the organic semiconductor material 20 may be required depending upon the material and formulation used.

Subsequently a dielectric 22 is coated over the entire area of the organic semiconductor material 20. Suitable dielectric materials 22 include fluorinated polymers, PVP and BCB. Suitable coating techniques include blade coating, spin coating, spray coating and flood printing. A thermal treatment of the dielectric 22 may be required depending upon the material and formulation used.

A gate electrode 24 is deposited and patterned upon the dielectric 22 using a vacuum deposition process through a shadow mask or by sputtering and subsequent photolithographic etching or lift-off. Alternatively the gate electrode 24 is printed from a nanoparticle suspension or other solution deposition technique. A suitable metal for the gate electrode 24 is gold, aluminium and silver.

Subsequently, the device stack is placed in a plasma etch chamber and the organic semiconductor material 20 and dielectric 22 layers are etched 38 for an appropriate time until they are completely removed. The plasma etch gaseous composition, power and process time depend upon the dielectric 22 and organic semiconductor material 20 composition and thickness as will be understood by a person skilled in the art. Suitable plasma etch gasses include O₂, CF₄ and mixes of these gases. Subsequently, an interconnect layer 40 is deposited and patterned upon where the layers have been etched 38. The interconnect layer 40 can be deposited by a vacuum deposition process through a shadow mask or by sputtering and subsequent photolithographic etching or lift-off.

With reference to FIG. 3, a schematic diagram of adjacent transistor and capacitor according to a third embodiment of the present invention comprises a substrate 14 bearing an etched and stacked top-gate organic semiconductor transistor 10 according to the first embodiment of the present invention and as illustrated in FIG. 1. The substrate 14 also bears a first metal contact 50 to form a first terminal of a capacitor 52. The first metal contact 50 can be deposited on the substrate 14 at the stage where the source electrode 16 and drain electrode 18 are deposited on the substrate 14.

An additional layer of dielectric 22A is coated over the entire area of the stacked top-gate organic semiconductor transistor 26 and metal contact 50. Subsequently, a second metal contact 54 is deposited on the additional layer of dielectric 22A to form a second terminal of the capacitor 52. Subsequently, the device stack is placed in a plasma etch chamber and the additional layer of dielectric 22A is removed to provide an isolated top-gate organic semiconductor transistor 26 and capacitor 52.

Referring to FIGS. 4 and 5, graphs of transistor properties before and after plasma etch were compared. Top-gate organic semiconductor transistors were fabricated and tested using the method of fabrication specified above and using an organic semiconductor material S1120 from suppliers Merck, a fluorinated dielectric D139 from suppliers Merck and an adhesion material M010 was applied to the dielectric to improve adhesion of a gate metal to the dielectric. The gate metal comprised aluminium and was deposited by thermal evaporation. The device stack was subjected to 30 minutes of O₂ plasma etch at 550 W and a further 10 minutes of O₂/CF₄ plasma at 600 W after which inspection revealed that all the exposed dielectric and organic semiconductor material was removed.

Original Measurement (65 days prior)

Saturation Calculations
Linear fit for threshold voltage and mobility
Forward scan
on-off ratio = 9E+04
mobility (cm² V⁻¹ s⁻¹) = 0.480
threshold voltage (V) = −3.5
Fit quality (R²) = 0.99
Gate current at −10 V Vgs (nA) = 7887
Onset voltage (V) = 0.5
subthreshold swing (V per decade) = 2.7
trap density (eV⁻¹ cm⁻²) = 7E+12
Reverse scan
on-off ratio = 1E+05
mobility (cm² V⁻¹ s⁻¹) = 0.485
threshold voltage (V) = −3.7
fit quality (R²) = 0.99
gate current at −10 V Vgs (nA) = 7379
onset voltage (V) = 0.0
subthreshold swing (V per decade) = 2.3
trap density (eV⁻¹ cm⁻²) = 6E+12
LINEAR CALCULATIONS
Mobility from transconductance
Forward scan
on-off ratio = 2E+08
peak mobility (cm² V⁻¹ s⁻¹) = 1.034
Voltage for peak mobility (V) = −13.25
gate current at −10 V Vgs (nA) = 7976
Reverse scan
on-off ratio = 1E+06
peak mobility (cm² V⁻¹ s⁻¹) = 1.032
Voltage for peak mobility (V) = −13.25
gate current at −10 V Vgs (nA) = 7976

After 3 × 10 min. 550 W O₂ and 1 ×
10 min. 600 W CF4/0₂ plasma treatment

SATURATION CALCULATIONS
Linear fit for threshold voltage and mobility
Forward scan
on-off ratio = 4E+04
mobility (cm² V⁻¹ s⁻¹) = 0.792
threshold voltage (V) = −1.5
Fit quality (R²) = 1.00
Gate current at −10 V Vgs (nA) = 22742
Onset voltage (V) = 0.5
subthreshold swing (v decade ⁻1) = 1.6
trap density (eV⁻¹ cm⁻²) = 4E+12
Reverse scan
on-off ratio = 4E+05
mobility (cm² V⁻¹ s⁻¹) = 0.796
threshold voltage (v) = −1.9
fit quality (R²) = 1.00
gate current at −10 V Vgs (nA) = 20610
onset voltage (V) = 0.0
subthreshold swing (V per decade) = 1.3
trap density (eV⁻¹ cm⁻²) = 4E+12
LINEAR CALCULATIONS
Mobility from transconductance
Forward scan
on-off ratio = 5E+04
peak mobility (cm² V⁻¹ s⁻¹) = 2.058
Voltage for peak mobility (V) = −12.75
gate current at −10 V Vgs (nA) = 8465
Reverse scan
on-off ratio = 2E+04
peak mobility (cm² V⁻¹ s⁻¹) = 0.727
Voltage for peak mobility (V) = −11.25
gate current at −10 V Vgs (nA) = 10046

The transistor properties measured before the plasma etch (FIG. 4) and after the plasma etch (FIG. 5) and in the above tables were compared. The data indicates that there was no overall degradation in performance after the plasma etch. There was in fact some improvement after 65 days stored in air and after all plasma treatments. The improved on-off ratio is evidence of reduced leakage through removal of the organic semiconductor material and dielectric which are not protected by the gate electrode.

No doubt many other effective alternatives will occur to the skilled person. It will be understood that the invention is not limited to the described embodiments and encompasses modifications apparent to those skilled in the art lying within the spirit and scope of the claims appended hereto.

1. A method of fabricating a top-gate organic semiconductor transistor comprising: providing a substrate; depositing source and drain electrodes over the substrate; depositing an organic semiconductor material in a channel between the source and drain electrodes and over at least a portion of the source and drain electrodes; depositing a dielectric material over the organic semiconductor material; depositing a gate electrode over the dielectric material and the organic semiconductor material in the channel; and removing a portion of the dielectric material and the organic semiconductor material, wherein the gate electrode acts as a mask to shield the underlying organic semiconductor material and dielectric material during the step of removing.

2. A method as claimed in claim 1, wherein the step of removing includes exposing the transistor to an etching process.

3. A method as claimed in claim 2, wherein the etching process includes exposing the transistor to a plasma etch.

4. A method as claimed in claim 3, wherein the plasma etch comprises an O₂ or CF₄ plasma etch.

5. A method as claimed in claim 1, wherein the step of depositing the dielectric material includes spin coating the dielectric material.

6. A method as claimed in claim 1, wherein the step of depositing the organic semiconductor material includes spin coating the organic semiconductor material.

7. A method as claimed in claim 1, wherein the organic semiconductor material is a polymer.

8. A method as claimed in claim 1 further comprising exposing a portion of the drain electrode following the step of removing.

9. A method as claimed in claim 8 further comprising depositing a conductive track over the exposed drain electrode and interconnecting the conductive track to an additional device.

10. A method as claimed in claim 9, wherein the additional device is an organic light emitting diode or an additional transistor.

11. A method as claimed in claim 1 further comprising exposing a portion of the substrate following the step of removing.

12. (canceled)
